(19) United States
(12) Patent Application Publication
(10) Pub. No.: US 2013/0342093 A1
(43) Pub. Date: Dec. 26, 2013

(54) HOUSING CASE

(71) Applicant: NEC Corporation, Tokyo (JP)

(72) Inventor: Shinichi Iwata, Tokyo (JP)

(73) Assignee: NEC Corporation, Tokyo (JP)

(21) Appl. No.: 13/899,662

(22) Filed: May 22, 2013

(30) Foreign Application Priority Data
Jun. 25, 2012 (JP) 2012-141708

(51) Int. Cl. H05K 5/02

(52) U.S. Cl. CPC H05K 5/0295
USPC 312/319.1

(57) ABSTRACT

A housing case of the present invention includes an ejection force applying unit mounted in a case body and applying a force to eject a housed object toward an insertion opening, to the housed object. The ejection force applying unit has a wound part formed by winding one end side of a spring member and a fixed part formed by fixing the other end side of the spring member inside the case body, and includes a cylindrical member housing the wound part in a cylinder thereof. An extraction opening through which the other end of the spring member can be extracted outside from inside the cylinder so as to be fixed inside the case body is formed on the cylindrical member. The cylindrical member moves in the case body in contact with the housed object inserted in the case body.

### INCORPORATION BY REFERENCE

This application is based upon and claims the benefit of priority from Japanese patent application No. 2012-141708, filed on Jun. 25, 2012, the disclosure of which is incorporated herein in its entirety by reference.

### TECHNICAL FIELD

The present invention relates to a housing case, more specifically, relates to a housing case which has a function of ejecting an object housed therein.

### BACKGROUND ART

A medium for storing data in a storage device is, for example, a magnetic tape, an optical disk, a magneto-optical disk and a magnetic disk, and the storing medium configures a cartridge so as to be capable of being attached to and detached from the storage device. An unused or already-recorded cartridge is housed and held in a library which can house several or several dozen cartridges.

A small-size magnetic tape library which can house several or several dozen cartridges is mounted on a universal 19-inch rack and used. The equipment dimension of the magnetic tape library is limited by the size of the general 19-inch rack. Therefore, the magnetic tape library requires increase of the number of cartridges that can be housed therein, namely, increase of the efficiency of housing.

In general, a “magazine” which houses a plurality of cartridges is configured by “cells” for housing cartridges. Although one “cell” can generally house one cartridge, a deep cell using a constant force spring has been devised as a means for increasing the efficiency of housing as shown in Patent Document 1. To be specific, a deep cell has a configuration that the open end of a constant force spring formed by a thin plate closely wound at constant curvature is fixed within a cell. When a cartridge is inserted into the cell, the constant force spring is pushed and stretched by the cartridge and the spring is moved in the cell. A restoring force caused by the constant force spring having been stretched acts so as to push out the cartridge from inside the cell.
Patent Document 1: International Publication No. 2009-041374

However, regarding the housing case disclosed by Patent Document 1 described above, because the constant force spring is wound with a metallic part thereof bare, there is a problem that, when a cartridge having a rough face is inserted into or ejected from the cell, the constant force spring may rotate while the metallic part is in contact with the cartridge and the cartridge may be damaged. Moreover, there is a problem that a noise is generated at a part where the constant force spring comes in contact with the cartridge. Such a problem may arise in not only a housing case for housing a cartridge of a data storing medium such as a magnetic tape but also a housing case for housing any housed object.

### SUMMARY

Accordingly, an object of the present invention is to provide a housing case which can solve the abovementioned problems, damage of a housed object and generation of a noise.

A housing case as an exemplary embodiment of the present invention is a housing case including:

a case body that houses therein a housed object inserted through an insertion opening; and

an ejection force applying unit that is mounted in the case body and that applies a force to eject the housed object having been housed toward the insertion opening, to the housed object, wherein:

the ejection force applying unit has a wound part formed by winding one end side of a spring member having a predetermined length and a fixed part formed by fixing open other end side of the spring member inside the case body, and also includes a cylindrical member covering an outer periphery of the wound part and housing the wound part in a cylinder thereof, and an extraction opening through which the open other end of the spring member can be extracted outside from inside the cylinder so as to be fixed inside the case body is formed on the cylindrical member; and

the cylindrical member is configured to, when the cylindrical member is pushed by the housed object and thereby moves inward in the case body in a state that the cylindrical member is in contact with the housed object inserted in the case body, stretch the spring member having been wound at the wound part housed in the cylindrical member and, when the cylindrical member moves toward the insertion opening of the case body due to a restoring force of the spring member from a stretched state to a wound state, push the housed object toward the insertion opening of the case body.

Further, a housing method as another exemplary embodiment of the present invention is a housing method by a housing case that includes: a case body that houses therein a housed object inserted through an insertion opening; and an ejection force applying unit that is mounted in the case body and that applies a force to eject the housed object having been housed toward the insertion opening, to the housed object, wherein:

the ejection force applying unit has a wound part formed by winding one end side of a spring member having a predetermined length and a fixed part formed by fixing open other end side of the spring member inside the case body, and also includes a cylindrical member covering an outer periphery of the wound part and housing the wound part in a cylinder thereof, and an extraction opening through which the open other end of the spring member can be extracted outside from inside the cylinder so as to be fixed inside the case body is formed on the cylindrical member; and

the cylindrical member is configured to, when the cylindrical member is pushed by the housed object and thereby moves inward in the case body in a state that the cylindrical member is in contact with the housed object inserted in the case body, stretch the spring member having been wound at the wound part housed in the cylindrical member and, when the cylindrical member moves toward the insertion opening of the case body due to a restoring force of the spring member from a stretched state to a wound state, push the housed object toward the insertion opening of the case body.

With the configurations as described above, the present invention can provide a housing case which can inhibit damage of a housed object and generation of a noise.

### BRIEF DESCRIPTION OF DRAWINGS

FIG. 1 is a view showing a configuration of a constant force spring configuring a housing case in a first exemplary embodiment of the present invention;

FIG. 2 is a view showing a configuration of a spring case configuring the housing case in the first exemplary embodiment of the present invention;

FIG. 3 is a view showing a configuration when the constant force spring disclosed in FIG. 1 is housed in the spring case disclosed in FIG. 2 in the housing case in the first exemplary embodiment of the present invention;

FIG. 4 is a view showing a configuration of the housing case in the first exemplary embodiment of the present invention;

FIG. 5a is a view showing a state in which one housed object is housed in the housing case in the first exemplary embodiment of the present invention;

FIG. 5b is a view showing a state in which two housed objects are housed in the housing case in the first exemplary embodiment of the present invention;

FIG. 6 is a view showing a configuration of a magnetic tape library in a second exemplary embodiment of the present invention;

FIG. 7 is a view showing a magazine mounted in the magnetic tape library in the second exemplary embodiment of the present invention; and

FIG. 8 is a view showing a state in which an upper face cover of the magazine mounted in the magnetic tape library in the second exemplary embodiment of the present invention is removed.

### EXEMPLARY EMBODIMENT

### First Exemplary Embodiment

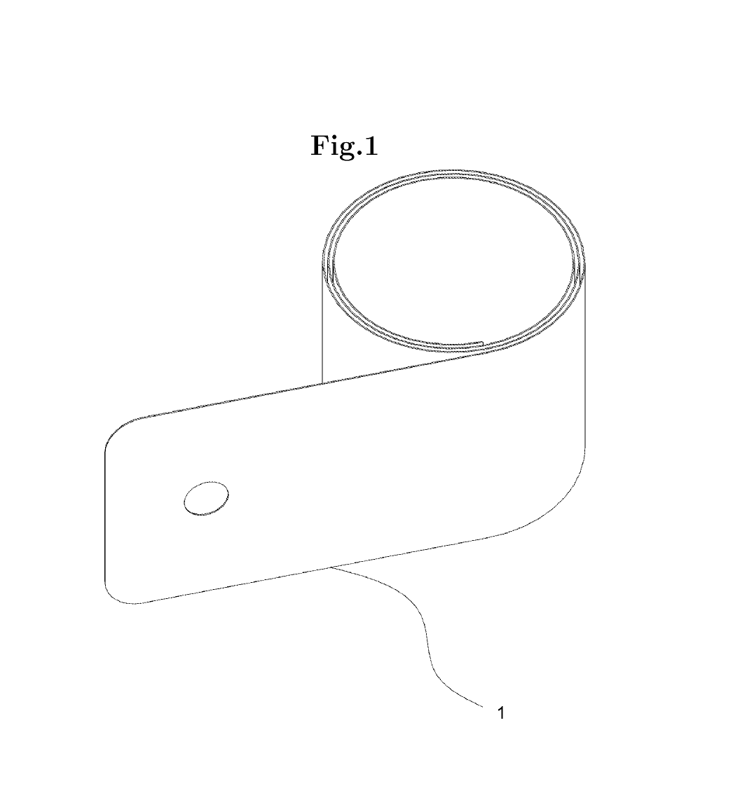

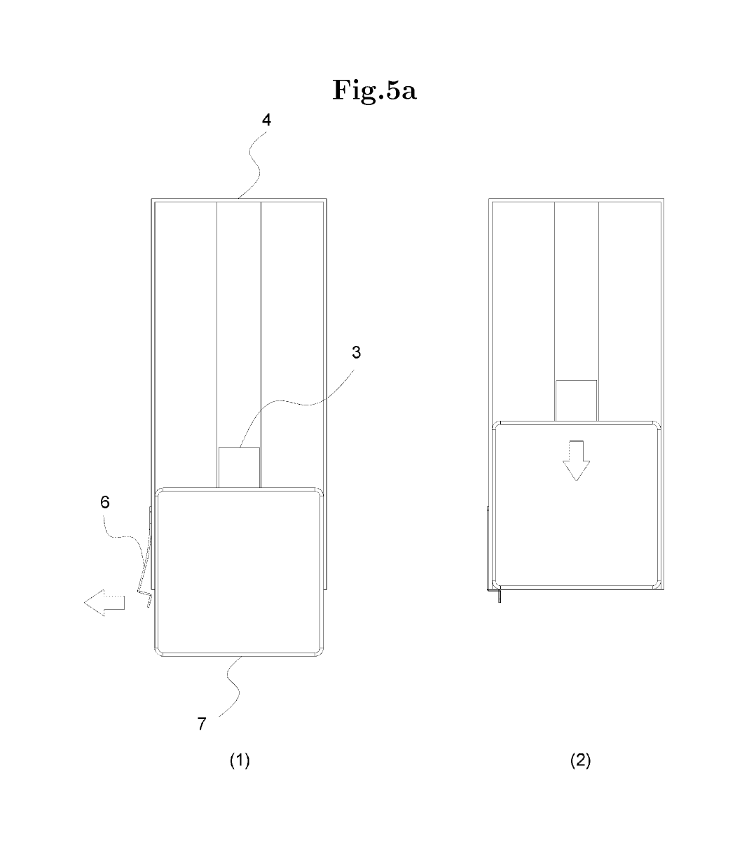

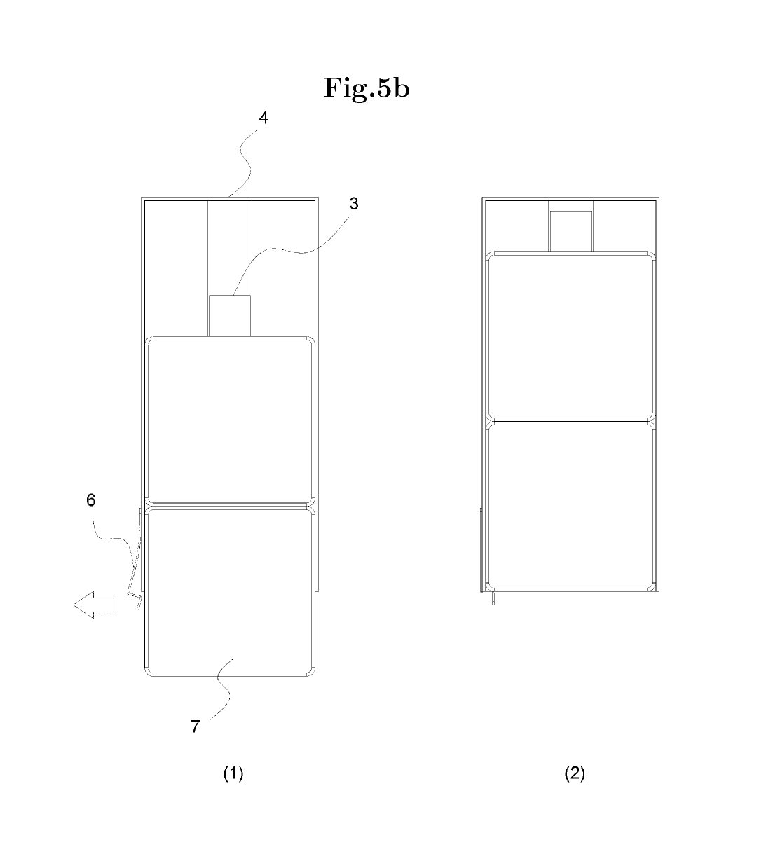

A first exemplary embodiment of the present invention will be described with reference to FIGS. 1 to 5b. FIGS. 1 to 4 are views for describing a configuration of a housing case in this exemplary embodiment, and FIGS. 5a and 5b are views for describing an operation of the housing case.

### [Configuration]

First, the housing case described in this exemplary embodiment houses a box-shaped housed object such as a magnetic tape cartridge. However, the housing case may house any housed objected, and the shape of a housed shaped to be housed therein is not limited to a box shape.

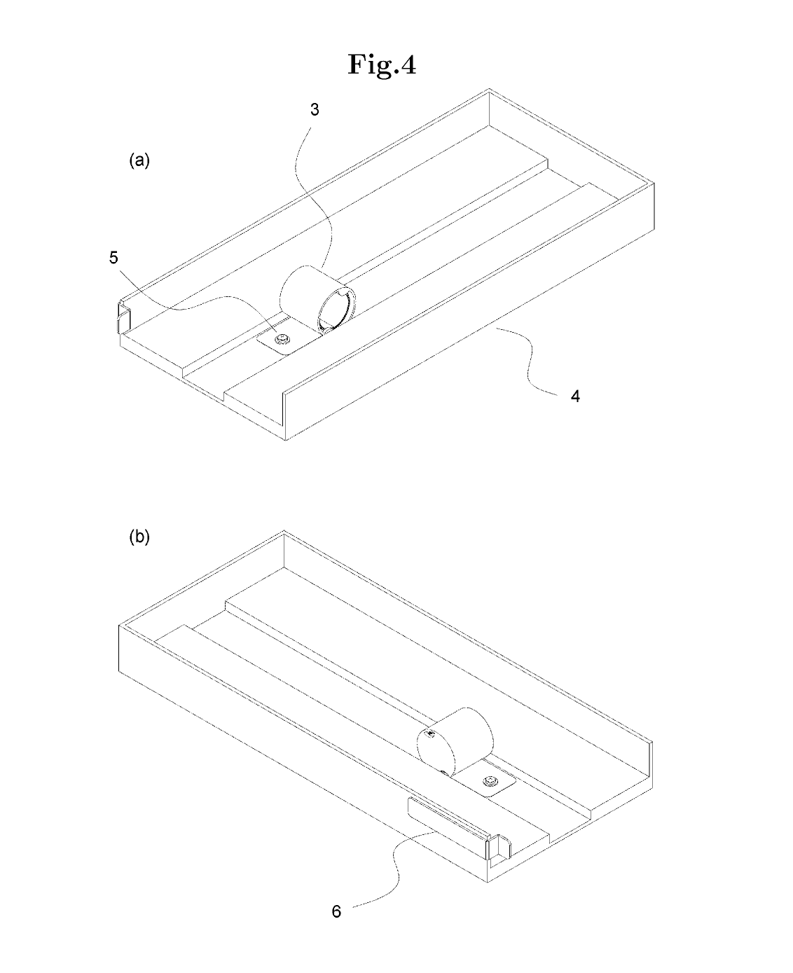

The overview of the housing case in this exemplary embodiment is shown in FIGS. 4(a) and 4(b). FIGS. 4(a) and 4(b) are perspective views of the housing case taken from different directions, respectively, and illustrate by omitting part of the configuration for convenience of description as described later.

As shown in FIGS. 4(a) and 4(b), the housing case in this exemplary embodiment has a box-shaped case body 4, which is almost rectangular-parallelepiped, for housing a housed object 7. Although the case body 4 shown in FIGS. 4(a) and 4(b) are illustrated with the upper face opened, the upper face is usually closed. Therefore, the case body 4 is formed into a shape that only the side face on one end in the longitudinal direction is opened, and the opened side face is an opening for insertion of the housed object 7. In other words, when the housed object 7 is housed into the housing case, the housed object 7 is inserted through the insertion opening, and the housed object 7 is ejected through the insertion opening as described later.

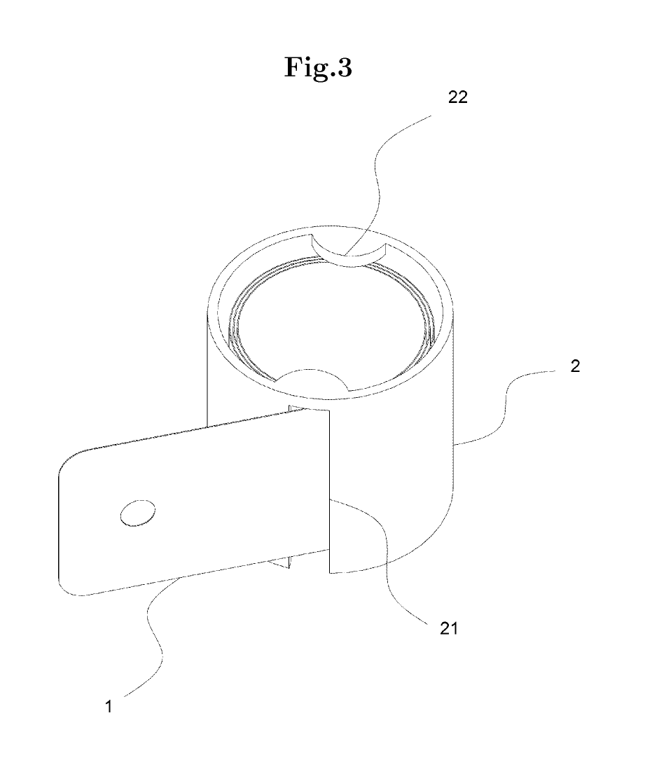

Further, the housing case is provided with a spring module 3 (an ejection force applying unit) that applies a force of ejecting the housed object 7 housed in the housing case toward the insertion opening to the housed object 7 (refer to FIG. 5a). The spring module 3 is configured by the spring case 2 having a shape of an almost circular cylinder and a constant force spring 1 housed in the cylinder of the spring case 2. In other words, the spring module 3 is in a state that the constant force spring 1 is installed in the spring case 2 as shown in FIG. 3. A configuration of the spring module 3 will be described in detail with reference to FIGS. 1 to 3.

FIG. 1 is an external view of the constant force spring 1. The constant force spring 1 is made by closely winding a spring member having a predetermined length and having a thin plate shape from one end thereof, and the other end thereof is an open end. In other words, as shown in FIG. 1, the constant force spring 1 has a wound part which is wound and formed into a shape of a circular cylinder, and the opened other end is fixed inside the case body 4 by a screw or the like as described later to configure a fixed part 5.

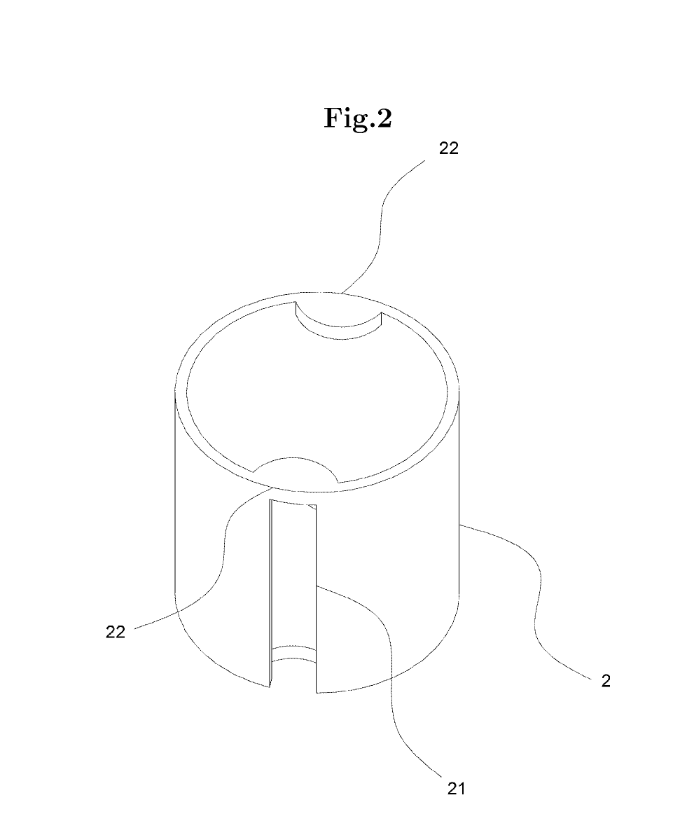

FIG. 2 is an external view of the spring case 2 that the wound part of the constant force spring 1 is housed. The spring case 2 in this exemplary embodiment is made of resin. The spring case 2 is not limited to being made of resin and can be made of any material, but it is desirable that the spring case 2 is made of a material whose hardness is the same as or smaller than the hardness of a material forming the exterior of the housed object 7.

The spring case 2 is formed into a shape of an almost circular cylinder whose inner diameter is the same as or slightly larger than the outer diameter of the wound part that is the circular-cylindrical part of the constant force spring 1 described above so as to be capable of covering the periphery (of the outer diameter) of the wound part and housing the wound part inside the cylinder. Moreover, the spring case 2 having a circular-cylindrical shape is formed so that the length in the height direction of the cylinder is longer than the length in the height direction of the wound part of the constant force spring 1.

The spring case 2 is formed with one end in the height direction of the cylinder closed, and the other end is opened so that the constant force spring 1 can be inserted into the cylinder therethrough. Moreover, two flanges 22 that are protruding parts protruding inwards from the cylinder provided on the perimeter on the opened side of the spring case 2. These flanges 22 are engaged with the constant force spring 1 housed in the cylinder of the spring case 2 so that the constant force spring 1 does not move outside from the opened side of the spring case 2. The number of the flanges 22 and the positions to form the flanges 22 are not limited to the number and the positions shown in FIG. 2.

Further, the spring case 2 is provided with a slit 21 (an extraction opening) having a predetermined slit width along the longitudinal direction that is the height direction of the cylinder. The slit 21 is formed so that the length is longer than the plate width of the plate-like spring member configuring the constant force spring 1 and the slit width is wider than the plate thickness of the constant force spring 1. Consequently, it is possible to extract the open end of the constant force spring 1 housed in the spring case 2 from inside the cylinder.

Next, with reference to FIG. 3, a configuration that the constant force spring 1 is set in the abovementioned spring case 2 will be described. First, the constant force spring 1 is inserted into the cylinder through the opened end of the spring case 2 in a state that the constant force spring 1 is wound up to the open end thereof. At this moment, the constant force spring 1 is inserted into the cylinder of the spring case 2 in a tightly wound state so that the outer diameter of the wound part of the constant force spring 1 becomes smaller than in a normal state, namely, so that the outer diameter of the wound part becomes smaller than a length between protruding ends of the flanges 22 protruding inwards from the cylinder of the spring case 2. The constant force spring 1 is loosed from the tightly wound state after inserted, whereby the outer diameter of the wound part of the spring case 2 becomes larger than the length of the protruding ends of the flanges 22, and the constant force spring 1 is located inward from the flanges 22. Consequently, the constant force spring 1 is engaged so as not to move outside from the opened side of the spring case 2.

Further, after the constant force spring 1 is inserted into the spring case 2, the constant force spring 1 is rotated, and the open end thereof is extracted outside through the slit 21 by a predetermined length. Consequently, the open end of the constant force spring 1 is extracted outside through the slit 21 of the spring case 2 in a state that the wound part of the constant force spring 1 is housed in the spring case 2.

Next, with reference to FIGS. 4(a) and 4(b), a configuration of the housing case with the spring module 3 mounted on the case body 4 will be described. As shown in FIGS. 4(a) and 4(b), the housing case is equipped with the spring module 3 mounted on the inner bottom face of the case body 4. In this state, in the middle of the inner bottom face of the case body 4, a groove having a width equal to or more than the length in the height direction of the cylinder of the spring case 2 is formed along the longitudinal direction of the case body 4. Then, by placing the spring module 3 in this groove, and fixing the open end of the constant force spring 1 extracted from the spring case 2 to the inner bottom face of the case body 4 by a screw, a fixed part 5 is formed. At this moment, the spring module 3 is placed and fixed closer to the insertion opening of the case body 4 in a manner that a length direction of the wound part of the constant force spring 1 when the wound part is stretched becomes the longitudinal direction of the case body 4, namely, becomes orthogonal to the insertion opening.

Consequently, as described later, the spring module 3 is pushed by the housed object 7 inserted into the case body 4, whereby the wound part of the constant force spring 1 is stretched and the wound part, namely, the spring case 2 moves in a direction away from the insertion opening along the groove formed on the inner bottom face of the case body 4, because the open end of the constant force spring 1 is fixed. Moreover, due to a restoring force from the stretched state to the wound state of the wound part of the constant force spring 1, the wound part, namely, the spring case 2 moves in a direction toward the insertion opening along the groove formed on the inner bottom face of the case body 4.

Further, as shown in FIGS. 4(a) and 4(b), a stopper 6 (an engaging unit) for holding a housed state of a housed object housed in the case body 4 is provided near the insertion opening of the case body 4. To be specific, the stopper 6 is formed by a spring member, and is movable between a setting state that a front end thereof covers part of the insertion opening and a setting state that the stopper 6 bends as shown in FIG. 5a−(1) and terminates covering part of the insertion opening. Consequently, the stopper 6 prevents ejection of the housed object 7 housed in the case body 4 in the setting state of covering part of the insertion opening, and allows ejection of the housed object 7 housed in the case body 4 in the setting state of terminating covering part of the insertion opening.

### [Operation]

Next, with reference to FIGS. 5a and 5b, an operation of the abovementioned housing case will be described. First, as shown in FIG. 5a−(1), the user moves the stopper 6 in the arrow direction to bend the stopper 6, and inserts the housed object 7 inward (upward in the drawing) through the insertion opening of the case body 4. Then, the spring case 2 of the spring module 3 is pushed by the housed object 7 in a state that the housed object 7 is in contact with the spring case 2, and the spring case 2 moves inward along the groove formed on the inner bottom face of the case body 4.

At this moment, the constant force spring 1 configuring the spring module 3 is brought into a state that the wound part is stretched, because the open end is fixed to the inner bottom face of the case body 4 and the wound part is housed in the spring case 2. Then, due to a restoring force of the stretched constant force spring 1, a force to return the spring case 2 to its original position acts, and a bias force toward the insertion opening is applied to the housed object 7. However, when the housed object 7 is housed in the case body 4, as shown in FIG. 5a−(2), the stopper 6 returns to its original position due to a restoring force thereof and the housed object 7 is engaged with the stopper 6 so as to stay in the case body 4.

When the aforementioned spring case 2 moves inward in the case body 4, the spring case 2 is in contact with the housed object 7, but the spring case 2 does not rotate relative to the housed object 7. This is because the open end of the constant force spring 1 is fixed to the case body 4 in a state that the open end is extracted outside through the slit 21 formed on the spring case 2. Consequently, the spring case 2 and the housed object 7 do not move relative to each other though they are in contact with each other, with the result that it is possible to inhibit damage of the housed object 7, and it is also possible to inhibit of generation of a noise.

Next, at the time of inserting a second housed object 7, in the same manner as shown in FIG. 5a−(1), the stopper 6 is moved and brought into the state of terminating covering the insertion opening, and the housed object 7 is inserted into the case body 4 by pressing the rear face of the housed object 7 as shown in FIG. 5b−(1). Then, in the same manner as described above, the spring case 2 is pressed by the housed object 7 and moved more inward in the case body 4, whereby the constant force spring 1 is brought into a more stretched state. At this moment, due to the restoring force of the constant force spring 1, a bias force toward the insertion opening is applied to the housed object 7 by the spring case 2. However, when the housed object 7 is housed in the case body 4, the stopper 6 returns to its original position due to the restoring force thereof and the second housed object 7 is engaged so as to stay in the case body 4 as shown in FIG. 5b−(2).

At the time of taking out the housed object 7 from inside the case body 4 later, the stopper 6 is moved to be in the state of terminating covering the insertion opening as shown by the arrow in FIG. 5b−(1). Then, due to the restoring force of the constant force spring 1 described above, the spring case 2 moves toward the insertion opening, a force toward the insertion opening is applied to the housed objects 7, and both the two housed objects 7 are ejected from inside the case body 4.

At this moment, the spring case 2 moves toward the insertion opening in contact with the housed object 7 and thereby applies an ejection force to the housed object 7, but the spring case 2 does not rotate relative to the housed object 7. This is because the open end of the constant force spring 1 is fixed to the case body 4 in a state that the open end is extracted through the slit 21 formed on the spring case 2. Consequently, the spring case 2 and the housed object 7 are in contact with each other, but do not rotate relative to each other, with the result that it is possible to inhibit damage of the housed object 7, and it is also possible to inhibit generation of a noise.

Although a case of using the constant force spring 1 formed by winding a thin-plate spring member having a predetermined length as a spring member configuring the spring module 3 has been described above, the spring member is not limited to the constant force spring 1. Instead of the constant force spring 1, a spring member having another shape or configuration may be used. Moreover, a method of fixing the open end of the constant force spring 1 to the case body 4 is not limited to fixture by a screw and may be any method, such as press-fitting insertion and heat sealing.

Further, as well as the configuration and shape of a spring member configuring the spring module 3, the shape of the spring case 2 is not limited to the abovementioned one. For example, the shape of the spring case 2 is not limited to a circular-cylindrical shape, and can be any cylindrical shape. Moreover, the shape of the slit 21 is not limited to the abovementioned one, and may be an opening having any shape as far as it is an opening through which the open end of a spring member corresponding to the constant force spring 1 can be extracted from inside the spring case 2.

Further, although a case that one end of the spring case 2 is closed and the opening other end is provided with the flanges 22 has been described above, the spring case 2 can have any configuration, such as the one end thereof is also provided with the flanges 22, as far as the constant force spring 1 housed in the spring case 2 is prevented from moving outside.

### Second Exemplary Embodiment

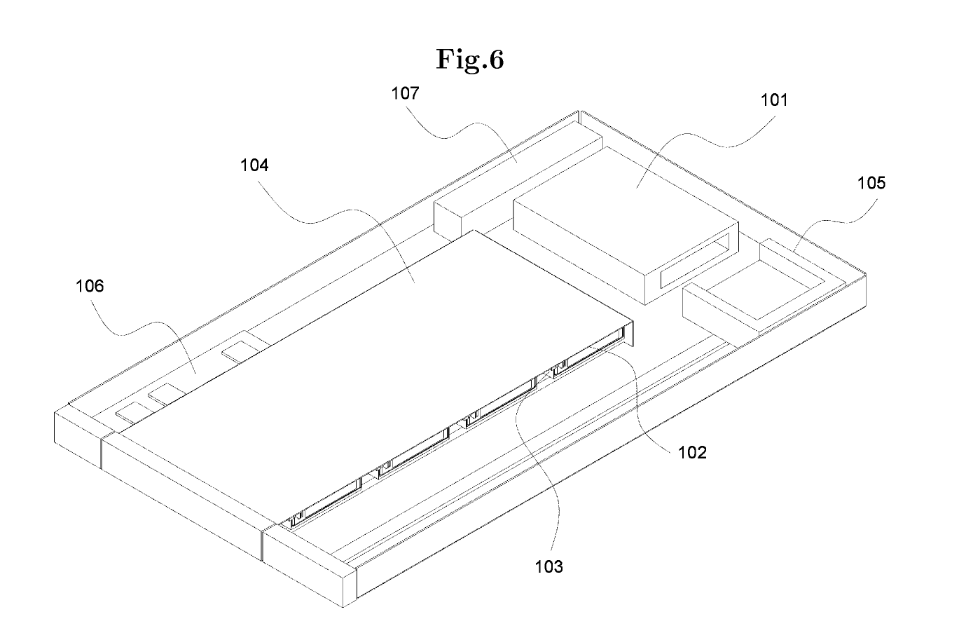

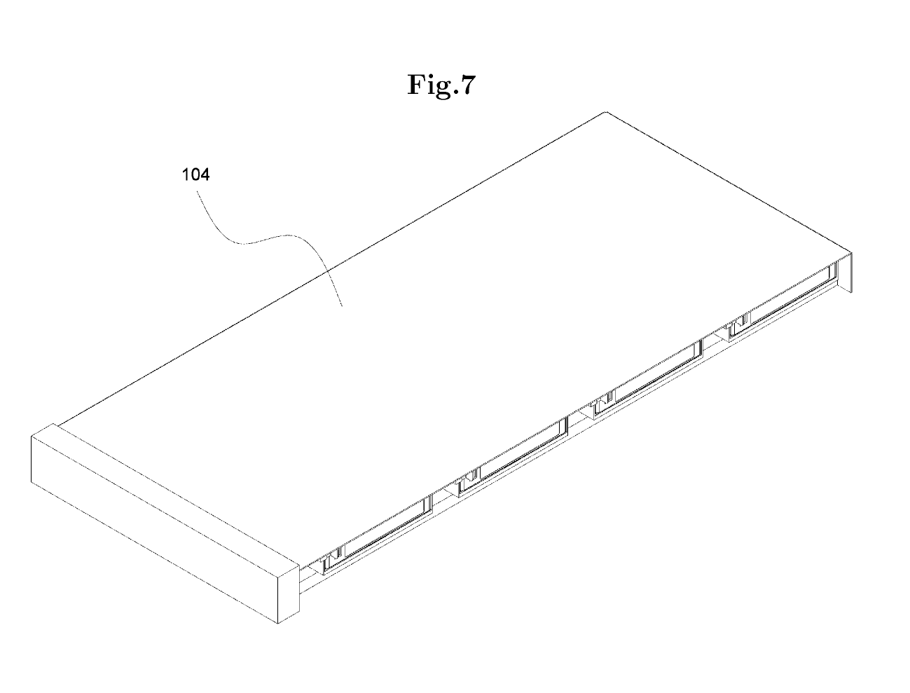

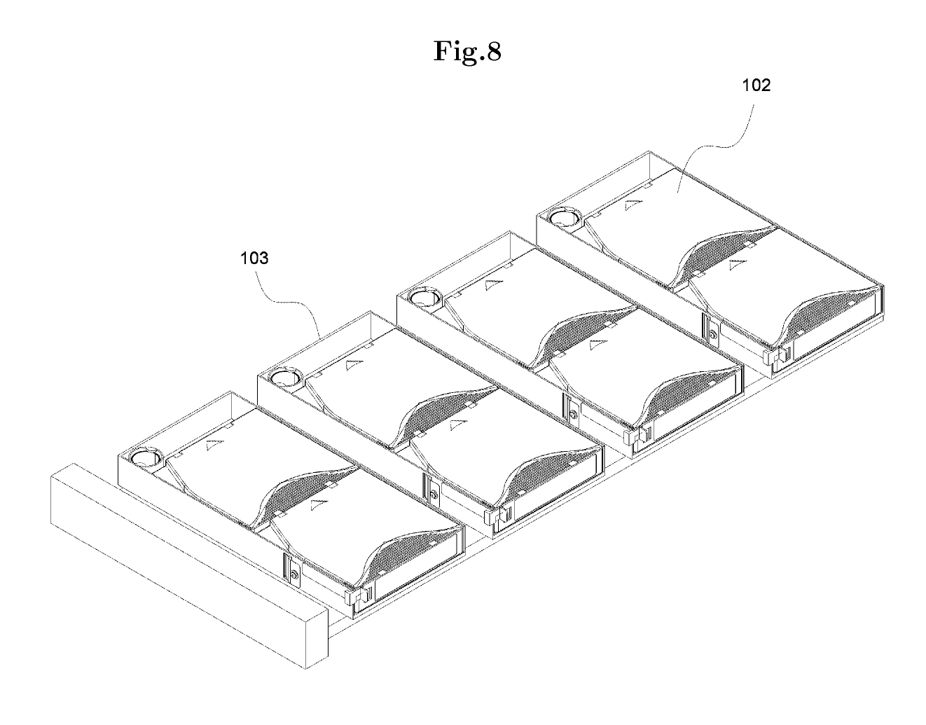

Next, a second exemplary embodiment of the present invention will be described with reference to FIGS. 6 to 8. FIG. 6 is a view showing a configuration of a magnetic tape library. FIG. 7 is an external view of a magazine configuring the magnetic tape library, and FIG. 8 is a view showing a state that the cover of the magazine is removed.

In this exemplary embodiment, a case of applying the abovementioned housing case to a magnetic tape library will be described. In this case, a cartridge 102 including a recording medium like a magnetic tape which can store and reproduce data is a housed object. A cartridge including, other than a magnetic tape, a recording medium such as an optical disk, a magneto-optical disk and a magnetic disk can also be a housed object.

First, with reference to FIG. 6, a configuration of a typical magnetic tape library will be described. The magnetic tape library includes a magnetic tape drive 101 for reading from and writing into the cartridge 102, cells 103 each for housing the cartridge 102, and a magazine 104 that is an assembly of the cells. Moreover, the magnetic tape library includes an accessor 105 for conveying the cartridge 102 housed in the cell 103 to the magnetic tape drive 101, a control board 106 for controlling the operation of the accessor 105, and a power source 107 for supplying electric power to the magnetic tape drive 101, the accessor 105 and the control board 106.

FIG. 7 is an external view of the magazine 104 mounted in the magnetic tape library. FIG. 8 is a view showing a state that a cover placed on the upper face of the magazine 104 is removed. The magazine 104 is configured by a plurality of cells 103, and each of the cells 103 can house a plurality of cartridges 102. Then, the housing case according to the present invention described in the first exemplary embodiment is applied to each of the cells 103 of the magnetic tape library shown in FIG. 8. By thus mounting the cells 103 using the housing case according to the present invention in the magnetic tape library, it is possible to house the cartridges 102 in high density and, as described above, it is possible to prevent the constant force spring 1 from damaging the cartridge 102, and it is also possible to prevent generation of a noise.

### <Supplementary Notes>

The whole or part of the exemplary embodiments disclosed above can be described as the following supplementary notes. Below, schematic configurations of a housing case and a housing method according to the present invention will be described. However, the present invention is not limited to the following configurations.

### (Supplementary Note 1)

A housing case including:

a case body that houses therein a housed object inserted through an insertion opening; and

an ejection force applying unit that is mounted in the case body and that applies a force to eject the housed object having been housed toward the insertion opening, to the housed object, wherein:

the ejection force applying unit has a wound part formed by winding one end side of a spring member having a predetermined length and a fixed part formed by fixing open other end side of the spring member inside the case body, and also includes a cylindrical member covering an outer periphery of the wound part and housing the wound part in a cylinder thereof, and an extraction opening through which the open other end of the spring member can be extracted outside from inside the cylinder so as to be fixed inside the case body is formed on the cylindrical member; and

the cylindrical member is configured to, when the cylindrical member is pushed by the housed object and thereby moves inward in the case body in a state that the cylindrical member is in contact with the housed object inserted in the case body, stretch the spring member having been wound at the wound part housed in the cylindrical member and, when the cylindrical member moves toward the insertion opening of the case body due to a restoring force of the spring member from a stretched state to a wound state, push the housed object toward the insertion opening of the case body.

### (Supplementary Note 2)

The housing case according to Supplementary Note 1, wherein the cylindrical member is configured to move inside the case body in contact with the housed object inserted in the case body, without rotating relative to the housed object.

### (Supplementary Note 3)

The housing case according to Supplementary Note 1 or 2, wherein:

the spring member configuring the ejection force applying unit is formed into a thin plate having a predetermined length; and

the extraction opening formed on the ejection force applying unit is formed into a slit whose groove width is larger than a plate thickness of the spring member.

### (Supplementary Note 4)

The housing case according to any of Supplementary Notes 1 to 3, wherein the cylindrical member is formed with at least one end side opened so as to allow insertion and extraction of the spring member into and from the cylinder, and a protruding part that protrudes inward from the cylinder is provided on a perimeter on the opened side so as to be engaged to prevent the spring member from moving outside from inside the cylinder.

### (Supplementary Note 5)

The housing case according to any of Supplementary Notes 1 to 4, wherein the cylindrical member is made of resin.

### (Supplementary Note 6)

The housing case according to any of Supplementary Notes 1 to 5, wherein an engaging unit that can move so that it can be set between a state of preventing ejection of the housed object housed in the case body and a state of allowing ejection of the housed object is provided at the insertion opening of the case body.

### (Supplementary Note 7)

The housing case according to any of Supplementary Notes 1 to 6, wherein the case body houses, as the housed object, a cartridge including a recording medium that can store and reproduce data.

### (Supplementary Note 8)

A housing method by a housing case that includes: a case body that houses therein a housed object inserted through an insertion opening; and an ejection force applying unit that is mounted in the case body and that applies a force to eject the housed object having been housed toward the insertion opening, to the housed object, wherein:

the ejection force applying unit has a wound part formed by winding one end side of a spring member having a predetermined length and a fixed part formed by fixing open other end side of the spring member inside the case body, and also includes a cylindrical member covering an outer periphery of the wound part and housing the wound part in a cylinder thereof, and an extraction opening through which the open other end of the spring member can be extracted outside from inside the cylinder so as to be fixed inside the case body is formed on the cylindrical member; and

the cylindrical member is configured to, when the cylindrical member is pushed by the housed object and thereby moves inward in the case body in a state that the cylindrical member is in contact with the housed object inserted in the case body, stretch the spring member having been wound at the wound part housed in the cylindrical member and, when the cylindrical member moves toward the insertion opening of the case body due to a restoring force of the spring member from a stretched state to a wound state, push the housed object toward the insertion opening of the case body.

### (Supplementary Note 9)

The housing method according to Supplementary Note 8, wherein the cylindrical member is configured to move inside the case body in contact with the housed object inserted in the case body, without rotating relative to the housed object.

Although the present invention has been described above with reference to the exemplary embodiments and so on, the present invention is not limited to the exemplary embodiments described above. The configurations and details of the present invention can be altered in various manners that can be understood by those skilled in the art within the scope of the present invention.

1. A housing case comprising:
a case body that houses therein a housed object inserted through an insertion opening; and
an ejection force applying unit that is mounted in the case body and that applies a force to eject the housed object having been housed toward the insertion opening, to the housed object, wherein:
the ejection force applying unit has a wound part formed by winding one end side of a spring member having a predetermined length and a fixed part formed by fixing open other end side of the spring member inside the case body, and also includes a cylindrical member covering an outer periphery of the wound part and housing the wound part in a cylinder thereof, and an extraction opening through which the open other end of the spring member can be extracted outside from inside the cylinder so as to be fixed inside the case body is formed on the cylindrical member; and
the cylindrical member is configured to, when the cylindrical member is pushed by the housed object and thereby moves inward in the case body in a state that the cylindrical member is in contact with the housed object inserted in the case body, stretch the spring member having been wound at the wound part housed in the cylindrical member and, when the cylindrical member moves toward the insertion opening of the case body due to a restoring force of the spring member from a stretched state to a wound state, push the housed object toward the insertion opening of the case body.

2. The housing case according to claim 1, wherein the cylindrical member is configured to move inside the case body in contact with the housed object inserted in the case body, without rotating relative to the housed object.

3. The housing case according to claim 1, wherein:
the spring member configuring the ejection force applying unit is formed into a thin plate having a predetermined length; and
the extraction opening formed on the ejection force applying unit is formed into a slit whose groove width is larger than a plate thickness of the spring member.

4. The housing case according to claim 1, wherein the cylindrical member is formed with at least one end side opened so as to allow insertion and extraction of the spring member into and from the cylinder, and a protruding part that protrudes inward from the cylinder is provided on a perimeter on the opened side so as to be engaged to prevent the spring member from moving outside from inside the cylinder.

5. The housing case according to claim 1, wherein the cylindrical member is made of resin.

6. The housing case according to claim 1, wherein an engaging unit that can move so that it can be set between a state of preventing ejection of the housed object housed in the case body and a state of allowing ejection of the housed object is provided at the insertion opening of the case body.

7. The housing case according to claim 1, wherein the case body houses, as the housed object, a cartridge including a recording medium that can store and reproduce data.

8. A housing method by a housing case that includes: a case body that houses therein a housed object inserted through an insertion opening; and an ejection force applying unit that is mounted in the case body and that applies a force to eject the housed object having been housed toward the insertion opening, to the housed object, wherein:
the ejection force applying unit has a wound part formed by winding one end side of a spring member having a predetermined length and a fixed part formed by fixing open other end side of the spring member inside the case body, and also includes a cylindrical member covering an outer periphery of the wound part and housing the wound part in a cylinder thereof, and an extraction opening through which the open other end of the spring member can be extracted outside from inside the cylinder so as to be fixed inside the case body is formed on the cylindrical member; and
the cylindrical member is configured to, when the cylindrical member is pushed by the housed object and thereby moves inward in the case body in a state that the cylindrical member is in contact with the housed object inserted in the case body, stretch the spring member having been wound at the wound part housed in the cylindrical member and, when the cylindrical member moves toward the insertion opening of the case body due to a restoring force of the spring member from a stretched state to a wound state, push the housed object toward the insertion opening of the case body.

9. The housing method according to claim 8, wherein the cylindrical member is configured to move inside the case body in contact with the housed object inserted in the case body, without rotating relative to the housed object.
